(19) United States
(12) Patent Application Publication
(10) Pub. No.: US 2025/0293142 A1
(43) Pub. Date: Sep. 18, 2025

(54) SEMICONDUCTOR MODULE

(71) Applicant: Samsung Electronics Co., Ltd., Suwon-si (KR)

(72) Inventors: Kyungseob Oh, Suwon-si (KR); Yeohoon Yoon, Suwon-si (KR); Miae Seo, Suwon-si (KR); Sanghyeon Son, Suwon-si (KR); Haekyung An, Suwon-si (KR)

(73) Assignee: Samsung Electronics Co., Ltd., Suwon-si (KR)

(21) Appl. No.: 19/059,154

(22) Filed: Feb. 20, 2025

(30) Foreign Application Priority Data
Mar. 13, 2024 (KR) 10-2024-0034860

(51) Int. Cl. H01L 23/498; H01L 23/00; H01L 23/31

(52) U.S. Cl. CPC H01L 23/49838; H01L 23/49833; H01L 23/49861; H01L 24/08; H01L 23/3107; H01L 2224/08225

(57) ABSTRACT

A semiconductor module comprises a circuit substrate structure comprising a first conductive pad at an upper portion thereof, a semiconductor chip on the circuit substrate structure and comprising a second conductive pad at a lower portion thereof, a lead frame structure contacting the second conductive pad, a molding structure covering a surface of the semiconductor chip and a sidewall of the lead frame structure and comprising a recess at a lower surface facing the circuit substrate structure, and a first conductive connection member contacting the first conductive pad and the lead frame structure and bonding the first conductive pad and the lead frame structure with each other. A lower sidewall of the lead frame structure is exposed by the recess, and the first conductive connection member covers the lower sidewall of the lead frame structure exposed by the recess.

### CROSS-REFERENCE TO RELATED APPLICATIONS

This application claims priority to and the benefit under 35 U.S.C. § 119 (a)-(d) to Korean Patent Application No. 10-2024-0034860, filed on Mar. 13, 2024 in the Korean Intellectual Property Office (KIPO), the contents of which are herein incorporated by reference in their entirety.

### FIELD

Example embodiments relate to a semiconductor module, more particularly, a semiconductor module including a quad flat no-lead (QFN) package.

### SUMMARY

Example embodiments provide a semiconductor module having enhanced electrical characteristics.

According to example embodiments, there is provided a semiconductor module. The semiconductor module may comprise a circuit substrate structure comprising a first conductive pad at an upper portion thereof, a semiconductor chip on the circuit substrate structure and comprising a second conductive pad at a lower portion thereof, a lead frame structure contacting the second conductive pad, a molding structure covering a surface of the semiconductor chip and a sidewall of the lead frame structure and comprising a recess at a lower surface facing the circuit substrate structure, and a first conductive connection member contacting the first conductive pad and the lead frame structure and bonding the first conductive pad and the lead frame structure with each other. A lower sidewall of the lead frame structure may be exposed by the recess, and the first conductive connection member may cover the lower sidewall of the lead frame structure exposed by the recess.

According to example embodiments, there is provided a semiconductor module. The semiconductor module may comprise a circuit substrate structure comprising a first conductive pad at an upper portion thereof, a semiconductor chip on the circuit substrate structure and comprising a second conductive pad at a lower portion thereof, a lead frame structure contacting the second conductive pad, a molding structure covering a surface of the semiconductor chip and a portion of a sidewall of the lead frame structure, and a conductive connection member contacting a sidewall and an upper surface of the first conductive pad and a lower surface and a portion of a sidewall of the lead frame structure and bonding the first conductive pad and the lead frame structure with each other. A lower surface of the molding structure may not be flat. An upper surface of the conductive connection member may be higher than a lowermost surface of the molding structure.

According to example embodiments, there is provided a semiconductor module. The semiconductor module may comprise a circuit substrate structure, a semiconductor package and a second conductive connection member. The circuit substrate structure may comprise a first substrate, a first conductive pad on an upper surface of the first substrate, and an insulation pattern spaced apart from the first conductive pad on the upper surface of the first substrate. The semiconductor package may be disposed on the circuit substrate structure, and may comprise a lead frame structure, a semiconductor chip and a molding structure. The lead frame structure may comprise a first lead frame, a first conductive connection member and a second lead frame sequentially stacked in a vertical direction. The semiconductor chip may be disposed on the lead frame structure, and may comprise a second substrate and a second conductive pad beneath the second substrate and contacting the lead frame structure. The molding structure may cover a portion of a sidewall of the lead frame structure and a surface of the semiconductor chip. The second conductive connection member may contact the first conductive pad and the lead frame structure. The molding structure may comprise a recess at a lower surface thereof. A lower sidewall of the lead frame structure may be exposed by the recess, and the second conductive connection member may cover the lower sidewall of the lead frame structure exposed by the recess.

In the semiconductor module in accordance with example embodiments, the crack generation of the conductive connection member bonding and electrically connecting the circuit substrate structure and the lead frame structure included in the semiconductor package with each other may be prevented or reduced. Thus, the semiconductor module may have an enhanced structural stability and enhanced electrical characteristics.

### BRIEF DESCRIPTION OF THE DRAWINGS

FIG. 1 is a cross-sectional view illustrating a semiconductor module in accordance with example embodiments, and FIG. 2 is an enlarged cross-sectional view of region X of FIG. 1, according to some embodiments.

FIG. 3 is a cross-sectional view illustrating a lead frame structure in accordance with example embodiments.

### DETAILED DESCRIPTION

Hereinafter, example embodiments will be explained in detail with reference to the accompanying drawings. Hereinafter, a direction substantially parallel to an upper surface of a substrate may be referred to as a horizontal direction, and a direction substantially perpendicular to the upper surface of the substrate may be referred to as a vertical direction.

A QFN package includes a semiconductor chip, a lead frame under the semiconductor chip and electrically connected thereto, and a molding member covering the semiconductor chip and the lead frame. The QFN package is stacked on a circuit substrate including a conductive pad, and the conductive pad and the lead frame are bonded with each other through a conductive bump including solder so that the QFN package and the circuit substrate are electrically connected to each other to form a semiconductor module. Thus, a structural stability of the conductive bump is important in the semiconductor module.

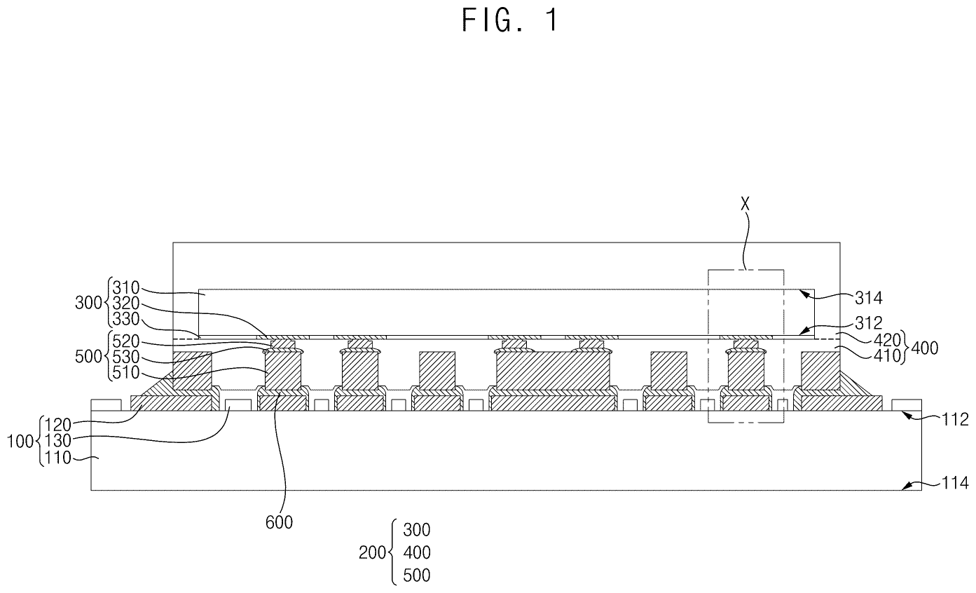

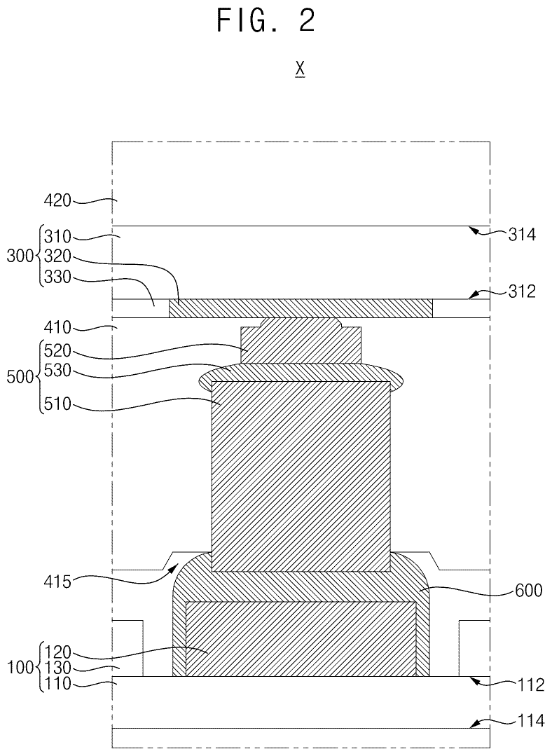

FIG. 1 is a cross-sectional view illustrating a semiconductor module in accordance with example embodiments, and FIG. 2 is an enlarged cross-sectional view of region X of FIG. 1, according to some embodiments.

Referring to FIGS. 1 and 2, the semiconductor module may include a circuit substrate structure 100, a semiconductor package 200 stacked on the circuit substrate structure 100, and a second conductive connection member 600 that may be disposed between the semiconductor package 200 and the circuit substrate structure 100 and electrically connecting the semiconductor package 200 and the circuit substrate structure 100.

In example embodiments, the circuit substrate structure 100 may be a printed circuit board (PCB), which may be a multi-layered circuit board including various types of circuit patterns therein. The circuit substrate structure 100 may include a first substrate 110, a first conductive pad 120 and an insulation pattern 130.

The first substrate 110 may include first and second surfaces 112 and 114 at opposite sides, respectively, in the vertical direction, and may include the circuit patterns therein.

The first conductive pad 120 may be disposed on the first surface 112 of the first substrate 110, and may be electrically connected to the circuit patterns, and a plurality of first conductive pads 120 may be spaced apart from each other in the horizontal direction. The first conductive pad 120 may include a metal (e.g., copper, nickel, gold, etc.).

In example embodiments, the first conductive pad 120 may be a non-solder mask defined (NSMD) pattern. Thus, the insulation pattern 130 may be disposed on the first surface 112 of the first substrate 110, and may be spaced apart from the first conductive pads 120 in the horizontal direction. That is, the insulation pattern 130 may contact neither an upper surface of each of the first conductive pads 120 nor a sidewall thereof, and an empty space may be formed between the insulation pattern 130 and each of the first conductive pads 120.

In example embodiments, the upper surface of the first conductive pad 120 may be higher than an upper surface of the insulation pattern 130.

The insulation pattern 130 may include, as an example, solder resist (SR).

In example embodiments, the semiconductor package 200 may be a QFN package. Thus, the semiconductor package 200 may include a semiconductor chip 300, a lead frame structure 500 and a molding structure 400 at least partially covering the semiconductor chip 300 and the lead frame structure 500.

The semiconductor chip 300 may include a second substrate 310 having first and second surfaces 312 and 314 at opposite sides, respectively, in the vertical direction, an insulating interlayer beneath the first surface 312 of the second substrate 310, and a second conductive pad 320 and a protective layer 330 beneath the insulating interlayer.

The second substrate 310 may include a semiconductor material (e.g., silicon, germanium, silicon-germanium, and/or a III-V group compound semiconductor such asGaP, GaAs, GaSb, etc.). In example embodiments, the second substrate 310 may be a silicon-on-insulator (SOI) substrate or a germanium-on-insulator (GOI) substrate.

A circuit device (e.g., a logic device or a memory device) may be disposed in the insulating interlayer. The logic device may include (e.g., a controller), and the memory device may include a volatile memory device such as a DRAM device, an SRAM device, etc., or a non-volatile memory device such as a flash memory device, an EEPROM device, etc. The circuit device may include circuit patterns (e.g., transistors, capacitors, wiring structures, etc.), and each of the wiring structures may include wirings, vias, contact plugs, conductive pads, etc., to list some examples.

The second conductive pad 320 may be electrically connected to the circuit patterns in the insulating interlayer. In example embodiments, a plurality of second conductive pads 320 may be spaced apart from each other in the horizontal direction. The second conductive pad 320 may include a metal, e.g., copper, nickel, gold, etc.

The protective layer 330 may be disposed beneath the insulating interlayer, and may cover a sidewall of the second conductive pad 320. In example embodiments, a lower surface of the protective layer 330 may be substantially coplanar with a lower surface of the second conductive pad 320. The protective layer 330 may include an insulating material (e.g., silicon oxide, silicon nitride, etc.).

The lead frame structure 500 may include a first lead frame 510 on the circuit substrate structure 100, and a first conductive connection member 530 and a second lead frame 520 sequentially stacked on the first lead frame 510 in the vertical direction.

In example embodiments, a plurality of first lead frames 510 may be spaced apart from each other in the horizontal direction, and a plurality of second lead frames 520 may be spaced apart from each other in the horizontal direction. The first lead frames 510 may be arranged to correspond to the first conductive pads 120, respectively, in the circuit substrate structure 100, and the second lead frames 520 may be disposed on some of the first lead frames 510.

The second lead frame 520 may be disposed on a corresponding one of the first lead frames 510, and the first conductive connection member 530 may be disposed between the first and second lead frames 510 and 520 so that the first and second lead frames 510 and 520 may be bonded with and electrically connected to each other. In example embodiments, the second lead frame 520 may include a lower portion having a first width in the horizontal direction and an upper portion having a second width in the horizontal direction smaller than the first width. The second lead frame 520 may contact the second conductive pad 320 included in the semiconductor chip 300 to be electrically connected thereto.

Each of the first and second lead frames 510 and 520 may include a metal (e.g., copper, nickel, gold, etc.), and the first conductive connection member 530 may include solder as an example.

The molding structure 400 may include a first molding member 410 and a second molding member 420 sequentially stacked in the vertical direction.

The first molding member 410 may be disposed beneath the semiconductor chip 300, and may cover a sidewall of the lead frame structure 500. That is, the first molding member 410 may cover sidewalls of the first lead frame 510, the first conductive connection member 530 and the second lead frame 520 sequentially stacked in the vertical direction. Additionally, the first molding member 410 may cover an upper surface of one of the first lead frames 510 on which the first conductive connection member 530 and the second lead frame 520 are not formed.

In example embodiments, a recess 415 (see FIG. 2) may be formed beneath a lower surface of the first molding member 410, and thus the lower surface of the first molding member 410 may not be flat. The recess 415 beneath the first molding member 410 may expose a lower sidewall of each of the first lead frames 510.

The recess 415 may be formed by performing a laser machining process, an etching process, and/or other processes, on the first molding member 410.

The second molding member 420 may cover a sidewall and an upper surface of the semiconductor chip 300.

Each of the first and second molding members 410 and 420 may include, in some embodiments, an epoxy molding compound (EMC), and in some cases, the first and second molding members 410 and 420 may be merged with each other.

The second conductive connection member 600 may be disposed between the first conductive pad 120 and the first lead frame 510, and may bond and electrically connect the first conductive pad 120 and the first lead frame 510 with each other. In example embodiments, the second conductive connection member 600 may cover a sidewall and an upper surface of the first conductive pad 120 and a lower surface and a lower sidewall of the first lead frame 510, and an upper portion of the second conductive connection member 600 may be disposed in the recess 415 beneath the lower surface of the first molding member 410.

Thus, an upper surface of the second conductive connection member 600 may be higher than a lower surface of the first molding member 410 beneath which no recess is formed, that is, a lowermost surface of the first molding member 410. Additionally, a width in the horizontal direction of the second conductive connection member 600 may be greater than a width in the horizontal direction of each of the first conductive pad 120 and the first lead frame 510.

The second conductive connection member 600 may include, in some embodiments, solder.

For example, if no recess is formed beneath the lower surface of the first molding member 410 and a sidewall of the first lead frame 510 is entirely covered by the first molding member 410, the second conductive connection member 600 bonding the first conductive pad 120 and the first lead frame 510 with each other may not cover a lower sidewall of the first lead frame 510 but may cover only the lower surface of the first lead frame 510. Thus, the second conductive connection member 600, which may bond and electrically connect the semiconductor package 200 and the circuit substrate structure 100 with each other, may not contact the first lead frame 510 at a sufficiently large area so that crack may be generated when the second conductive connection member 600 gets a physical impact or a thermal impact.

However, in example embodiments, the recess 415 may be formed beneath the lower surface of the first molding member 410 included in the semiconductor package 200, and the lower sidewall of the first lead frame 510 may be exposed by the recess 415, and thus the upper portion of the second conductive connection member 600 bonding the first conductive pad 120 of the circuit substrate structure 100 and the first lead frame 510 with each other may cover the lower sidewall of the first lead frame 510 as well as the lower surface of the first lead frame 510. Accordingly, the second conductive connection member 600 may contact the first lead frame 510 at an increased area, so that the generation of crack due to the physical and/or thermal impact may be reduced and that an electrical resistance between the first conductive pad 120 and the first lead frame 510 may be reduced.

As a result, the semiconductor module including the circuit substrate structure 100, the semiconductor package 200 bonded with the circuit substrate structure 100, and the second conductive connection member 600 electrically connecting the circuit substrate structure 100 and the semiconductor package 200 may have an enhanced structural stability and enhanced electrical characteristics.

FIGS. 1 and 2 show that the first lead frame 510 and the second conductive connection member 600 surrounding the lower sidewall of the first lead frame 510 do not entirely fill the recess 415 but a portion of the recess 415 remains as a space, and that a horizontal width of the second conductive connection member 600 is smaller than a horizontal width of the recess 415, however, the disclosure may not be limited thereto.

That is, the first lead frame 510 and the second conductive connection member 600 may entirely fill the recess 415, and in this case, the horizontal width of the second conductive connection member 600 may be substantially the same as the horizontal width of the recess 415. In example embodiments, the second conductive connection member 600 may fill the recess 415, and further, may be formed beneath a portion of the lower surface of the first molding member 410 adjacent to the recess 415. In this case, the horizontal width of the second conductive connection member 600 may be greater than the horizontal width of the recess 415.

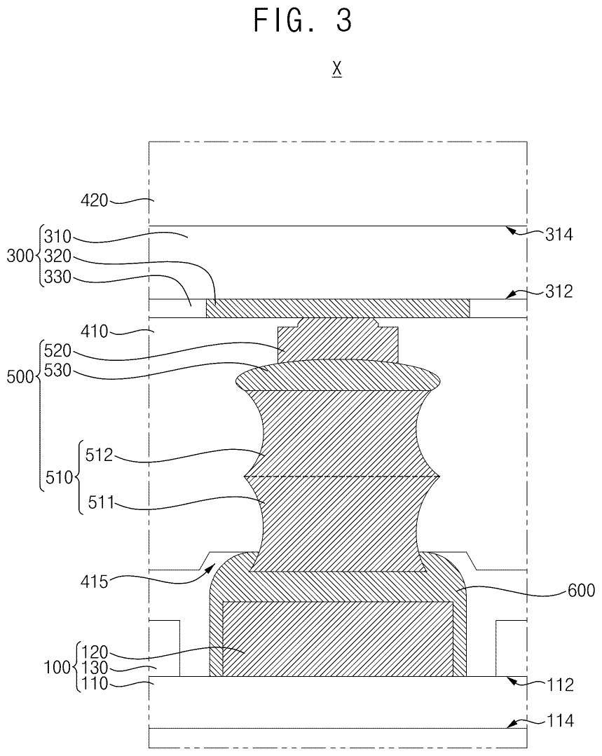

FIG. 3 is a cross-sectional view illustrating a lead frame structure in accordance with example embodiments, which may correspond to FIG. 2.

This lead frame structure may be substantially the same as or similar to that of FIGS. 1 and 2 except for the shape of the first lead frame, and thus repeated explanations are omitted herein.

Referring to FIG. 3, the first lead frame 510 may include first and second portions sequentially stacked in the vertical direction and contact each other.

In example embodiments, a central portion of each of the first and second portions of the first lead frame 510 may have a width greater than a width of each of lower and upper portions thereof, and a sidewall of each of the first and second portions of the first lead frame 510 may have a concave shape.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor module comprising:
a circuit substrate structure comprising a first conductive pad at an upper portion thereof;
a semiconductor chip on the circuit substrate structure, the semiconductor chip comprising a second conductive pad at a lower portion thereof;
a lead frame structure contacting the second conductive pad;
a molding structure covering a surface of the semiconductor chip and a sidewall of the lead frame structure, the molding structure comprising a recess at a lower surface facing the circuit substrate structure; and
a first conductive connection member contacting the first conductive pad and the lead frame structure and bonding the first conductive pad and the lead frame structure with each other,
wherein a lower sidewall of the lead frame structure is exposed by the recess, and the first conductive connection member covers the lower sidewall of the lead frame structure exposed by the recess.

2. The semiconductor module according to claim 1, wherein an upper surface of the first conductive connection member is higher than a lowermost surface of the molding structure.

3. The semiconductor module according to claim 1, wherein a width in a horizontal direction of the first conductive connection member is smaller than a width in the horizontal direction of the recess.

4. The semiconductor module according to claim 1, wherein the first conductive connection member covers a sidewall and an upper surface of the first conductive pad and a lower surface and the lower sidewall of the lead frame structure.

5. The semiconductor module according to claim 1, wherein the lead frame structure comprises a first lead frame, a second conductive connection member and a second lead frame sequentially stacked in a vertical direction, and
wherein each of the first and second lead frames comprises copper, and the second conductive connection member comprises solder.

6. The semiconductor module according to claim 5, wherein the first lead frame comprises first and second portions sequentially stacked in the vertical direction, and a sidewall of each of the first and second portions of the first lead frame has a concave shape.

7. The semiconductor module according to claim 5, wherein the first lead frame comprises first and second portions sequentially stacked in the vertical direction, and a width in a horizontal direction of the lower portion of the second lead frame is greater than a width in the horizontal direction of the upper portion of the second lead frame.

8. The semiconductor module according to claim 1, wherein the circuit substrate structure comprises:
a substrate;
the first conductive pad on an upper surface of the substrate; and
an insulation pattern spaced apart from the first conductive pad on the upper surface of the substrate.

9. The semiconductor module according to claim 1, wherein the molding structure comprises:
a first molding member beneath the semiconductor chip, the first molding member covering a sidewall of the lead frame structure; and
a second molding member on the first molding member, the second molding member covering an upper surface and a sidewall of the semiconductor chip.

10. A semiconductor module comprising:
a circuit substrate structure comprising a first conductive pad at an upper portion thereof;
a semiconductor chip on the circuit substrate structure, the semiconductor chip comprising a second conductive pad at a lower portion thereof;
a lead frame structure contacting the second conductive pad;
a molding structure covering a surface of the semiconductor chip and a portion of a sidewall of the lead frame structure; and
a conductive connection member contacting a sidewall and an upper surface of the first conductive pad and a lower surface and a portion of a sidewall of the lead frame structure and bonding the first conductive pad and the lead frame structure with each other,
wherein a lower surface of the molding structure is not flat, and
wherein an upper surface of the conductive connection member is higher than a lowermost surface of the molding structure.

11. The semiconductor module according to claim 10, wherein the lead frame structure comprises a first lead frame, a second conductive connection member and a second lead frame sequentially stacked in a vertical direction, and
wherein each of the first and second lead frames comprises copper, and the second conductive connection member comprises solder.

12. The semiconductor module according to claim 11, wherein the first lead frame comprises first and second portions sequentially stacked in the vertical direction, and a sidewall of each of the first and second portions of the first lead frame has a concave shape.

13. The semiconductor module according to claim 11, wherein the first lead frame comprises first and second portions sequentially stacked in the vertical direction, and a width in a horizontal direction of the lower portion of the second lead frame is greater than a width in the horizontal direction of the upper portion of the second lead frame.

14. The semiconductor module according to claim 10, wherein the circuit substrate structure comprises:
a substrate;
the first conductive pad on an upper surface of the substrate; and
an insulation pattern spaced apart from the first conductive pad on the upper surface of the substrate.

15. The semiconductor module according to claim 10, wherein the molding structure comprises:
a first molding member beneath the semiconductor chip, the first molding member covering a sidewall of the lead frame structure; and
a second molding member on the first molding member, the second molding member covering an upper surface and a sidewall of the semiconductor chip.

16. A semiconductor module comprising:
a circuit substrate structure comprising:
a first substrate;
a first conductive pad on an upper surface of the first substrate; and
an insulation pattern spaced apart from the first conductive pad on the upper surface of the first substrate;
a semiconductor package on the circuit substrate structure, the semiconductor package comprising:
a lead frame structure comprising a first lead frame, a first conductive connection member and a second lead frame sequentially stacked in a vertical direction;
a semiconductor chip on the lead frame structure, the semiconductor chip comprising:
a second substrate; and
a second conductive pad beneath the second substrate, the second conductive pad contacting the lead frame structure; and
a molding structure covering a portion of a sidewall of the lead frame structure and a surface of the semiconductor chip; and
a second conductive connection member contacting the first conductive pad and the lead frame structure,
wherein the molding structure comprises a recess at a lower surface thereof, and
wherein a lower sidewall of the lead frame structure is exposed by the recess, and the second conductive connection member covers the lower sidewall of the lead frame structure exposed by the recess.

17. The semiconductor module according to claim 16, wherein an upper surface of the second conductive connection member is higher than a lowermost surface of the molding structure.

18. The semiconductor module according to claim 16, wherein a width in a horizontal direction of the second conductive connection member is smaller than a width in the horizontal direction of the recess.

19. The semiconductor module according to claim 16, wherein the second conductive connection member covers a sidewall and an upper surface of the first conductive pad and a lower surface and the lower sidewall of the lead frame structure.

20. The semiconductor module according to claim 16, wherein the first lead frame comprises first and second portions sequentially stacked in the vertical direction, and a sidewall of each of the first and second portions of the first lead frame has a concave shape.
